(19) United States
(12) Patent Application Publication
(10) Pub. No.: US 2026/0324219 A1
(43) Pub. Date: Oct. 15, 2026

(54) DISPLAY DEVICE

(71) Applicant: Magnolia White Corporation, Tokyo (JP)

(72) Inventors: Hiroshi TABATAKE, Tokyo (JP); Yukio TANAKA, Tokyo (JP)

(73) Assignee: Magnolia White Corporation, Tokyo (JP)

(21) Appl. No.: 19/461,819

(22) Filed: Jan. 28, 2026

(30) Foreign Application Priority Data
Jan. 30, 2025 (JP) 2025-013924

(51) Int. Cl. H10K 59/131; H10K 59/122

(52) U.S. Cl. CPC H10K 59/131; H10K 59/122

(57) ABSTRACT

According to one embodiment, a display device includes first and second subpixels arranged in a first direction, a partition surrounding the first and second subpixels and having a slit extending in a second direction between the first and second subpixels, first and second pixel circuits driving the first and second subpixels, a first power line applying a power source voltage to the first pixel circuit, a second power line applying a power source voltage to the second pixel circuit, a first signal line applying a video signal to the first pixel circuit, and a second signal line applying a video signal to the second pixel circuit. The first and second signal lines do not overlap the slit in plan view.

### CROSS-REFERENCE TO RELATED APPLICATIONS

This application is based upon and claims the benefit of priority from Japanese Patent Application No. 2025-013924, filed Jan. 30, 2025, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. Some display devices of this type have touch detection functions for detecting user's operation with respect to a display area.

### BRIEF DESCRIPTION OF THE DRAWINGS

FIG. 1 is a view showing a configuration example of a display device according to the first embodiment.

FIG. 2 is a circuit diagram showing a configuration example applicable to a pixel circuit according to the first embodiment.

FIG. 3 is a schematic plan view showing an example of the arrangement mode of the pixel circuit according to the first embodiment.

FIG. 4 is a schematic plan view showing an example of the layout of subpixels according to the first embodiment.

FIG. 5 is a schematic cross-sectional view of the display device along the V-V line of FIG. 4.

FIG. 6 is a schematic plan view showing an example of a shape applicable to a touch detection electrode according to the first embodiment.

FIG. 7 is a schematic cross-sectional view of the display device along the VII-VII line of FIG. 6.

FIG. 8 is a schematic cross-sectional view showing an area in the vicinity of a slit in FIG. 7 in an enlarged manner.

FIG. 9 is a schematic cross-sectional view showing the configuration according to a comparative example.

FIG. 10 is a schematic plan view of a display area according to the second embodiment.

FIG. 11 is a schematic cross-sectional view of the display device along the XI-XI line of FIG. 10.

FIG. 12 is a schematic cross-sectional view of a display device according to the third embodiment.

FIG. 13 is a schematic cross-sectional view of a display device according to the fourth embodiment.

### DETAILED DESCRIPTION

In general, according to one embodiment, a display device includes a first subpixel and a second subpixel arranged in a first direction, a partition surrounding the first subpixel and the second subpixel and having a slit extending in a second direction crossing the first direction between the first subpixel and the second subpixel, a first pixel circuit configured to drive the first subpixel, a second pixel circuit configured to drive the second subpixel, a first power line applying a power source voltage to the first pixel circuit, a second power line applying a power source voltage to the second pixel circuit, a first signal line applying a video signal to the first pixel circuit, and a second signal line applying a video signal to the second pixel circuit. The first signal line and the second signal line do not overlap the slit in plan view.

According to another embodiment, a display device includes a first subpixel and a second subpixel arranged in a first direction, a partition surrounding the first subpixel and the second subpixel and having a slit extending in a second direction crossing the first direction between the first subpixel and the second subpixel, a first pixel circuit configured to drive the first subpixel, a second pixel circuit configured to drive the second subpixel, a first power line applying a power source voltage to the first pixel circuit, a second power line applying a power source voltage to the second pixel circuit, a first signal line applying a video signal to the first pixel circuit, a second signal line applying a video signal to the second pixel circuit, and a transparent conductive layer overlapping the slit in plan view.

According to still another embodiment, a display device includes a first subpixel and a second subpixel arranged in a first direction, a partition surrounding the first subpixel and the second subpixel and having a slit extending in a second direction crossing the first direction between the first subpixel and the second subpixel, a first pixel circuit configured to drive the first subpixel, a second pixel circuit configured to drive the second subpixel, a first power line applying a power source voltage to the first pixel circuit, a second power line applying a power source voltage to the second pixel circuit, a first signal line applying a video signal to the first pixel circuit, a second signal line applying a video signal to the second pixel circuit, and a metal layer located above the first signal line. At least a part of the first signal line overlaps the slit in plan view. The metal layer overlaps the part overlapping the slit of the first signal line in plan view.

Each embodiment can provide a display device capable of improving touch detection accuracy.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction along the X-axis is referred to as an X-direction (the first direction,) a direction along the Y-axis is referred to as a Y-direction (the second direction), and a direction along the Z-axis is referred to as a Z-direction (the third direction). Z-direction is a normal to the plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

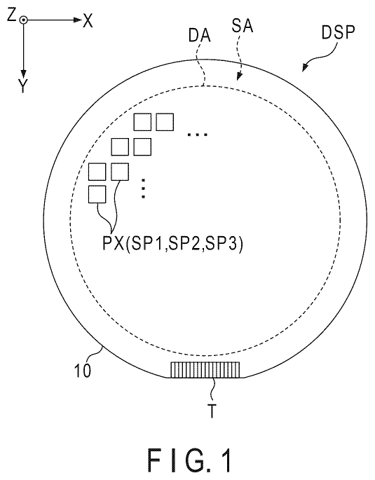

FIG. 1 is a view showing a configuration example of a display device DSP according to the first embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, each of the substrate 10 and the display area DA has a circular shape in plan view (a regular circle shape). The shape of each of the substrate 10 and the display area DA in plan view is not limited to this example and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP displaying mutually different colors. The present embodiment assumes a case where each pixel PX includes a blue subpixel SP1 (the first subpixel), a green subpixel SP2 (the second subpixel), and a red subpixel SP3 (the third subpixel). Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board applying voltage and signals for driving the display device DSP is connected to the terminal portion T.

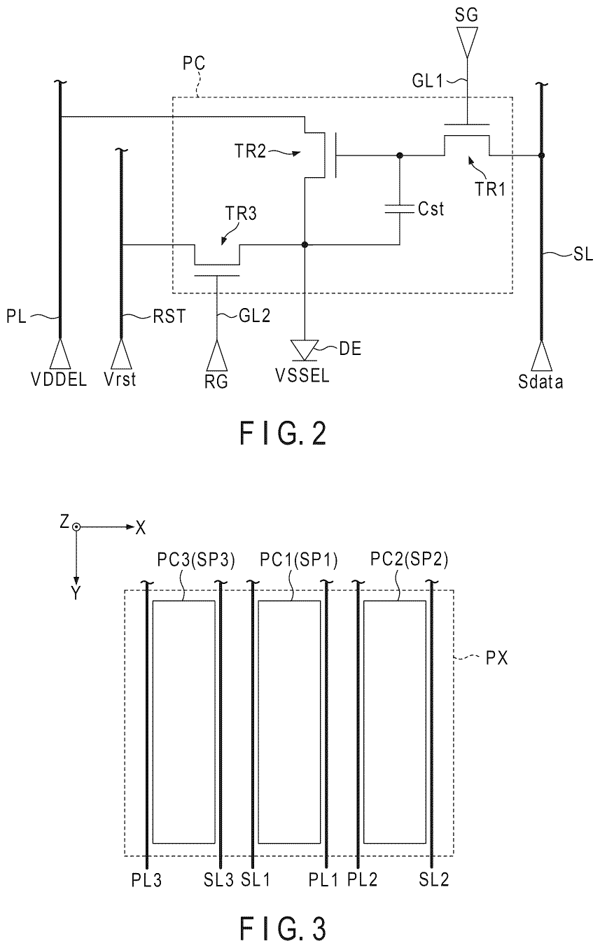

FIG. 2 is a circuit diagram showing a configuration example applicable to a pixel circuit PC, which each of the subpixels SP (SP1, SP2, and SP3) comprises. The pixel circuit PC shown in the figure includes three thin-film transistors TR1, TR2, and TR3 and one storage capacitor Cst. As an example of lines for applying signals or voltages to the pixel circuit PC, the display device DSP comprises a signal line SL, a power line PL, a reset line RST, and scanning lines GL1 and GL2.

In the following explanation, one of the source and drain electrodes of each of the thin-film transistors TR1 TR2, and TR3 is referred to as the first electrode, and the other is referred to as the second electrode. Similarly, one electrode of the storage capacitor Cst is referred to as the first electrode, and the other electrode is referred to as the second electrode.

The gate electrode of the thin-film transistor TR1 is connected to the scanning line GL1 supplying scanning signals SG. The gate electrode of the thin-film transistor TR3 is connected to the scanning line GL2 supplying scanning signals RG.

The first electrode of the thin-film transistor TR1 is connected to the signal line SL supplying video signals Sdata. The video signals Sdata are signals corresponding to a voltage written to the subpixels SP for image display. The first electrode of the thin-film transistor TR2 is connected to the power line PL applying a power source voltage VDDEL. The first electrode of the thin-film transistor TR3 is connected to the reset line RST applying a reset voltage Vrst.

The second electrode of the thin-film transistor TR1 is connected to the gate electrode of the thin-film transistor TR2 and the first electrode of the storage capacitor Cst. The second electrode of the thin-film transistor TR2 is connected to the anode of the display element DE and the second electrode of the storage capacitor Cst included in the subpixel SP. In the same manner, the second electrode of the thin-film transistor TR3 is connected to the anode of the display element DE and the second electrode of the storage capacitor Cst. The power source voltage VSSEL is applied to the cathode of the display element DE.

The configuration of the pixel circuit PC is not limited to the example shown in FIG. 2. For example, the number of transistors that the pixel circuit PC comprises may be two or less or four or more. Further, the pixel circuit PC may comprise the plurality of storage capacitors Cst.

FIG. 3 is a schematic plan view showing an example of the arrangement mode of the pixel circuit PC provided for one pixel PX. The following descriptions refer to the respective circuits PC of the subpixels SP1, SP2, and SP3 as pixel circuits PC1, PC2, and PC3. The respective signal lines SL applying the video signal Sdata to the pixel circuits PC1, PC2, and PC3 are referred to as signal lines SL1, SL2, and SL3 (the first to third signal lines). The respective power lines PL applying the power source voltage VDDEL to the pixel circuits PC1, PC2, and PC3 are referred to as power lines PL1, PL2, and PL3 (the first to third power lines).

In the example of FIG. 3, the pixel circuits PC3, PC1, and PC2 are arranged in the X-direction in this order. The signal line SL1 is located on the left side of the pixel circuit PC1, and the power line PL1 is located on the right side of the pixel circuit PC1. In contrast, the signal line SL2 is located on the right side of the pixel circuit PC2, and the power line PL2 is located on the left side of the pixel circuit PC2. Similarly, the signal line SL3 is located on the right side of the pixel circuit PC3, and the power line PL3 is located on the left side of the pixel circuit PC3.

In this manner, in the present embodiment, the positional relationship between the signal line SL1 and the power line PL1 in the X-direction is opposite to the positional relationship between the signal line SL2 and the power line PL2 in the X-direction. Similarly, the positional relationship between the signal line SL1 and the power line PL1 in the X-direction is opposite to the positional relationship between the signal line SL3 and the power line PL3 in the X-direction.

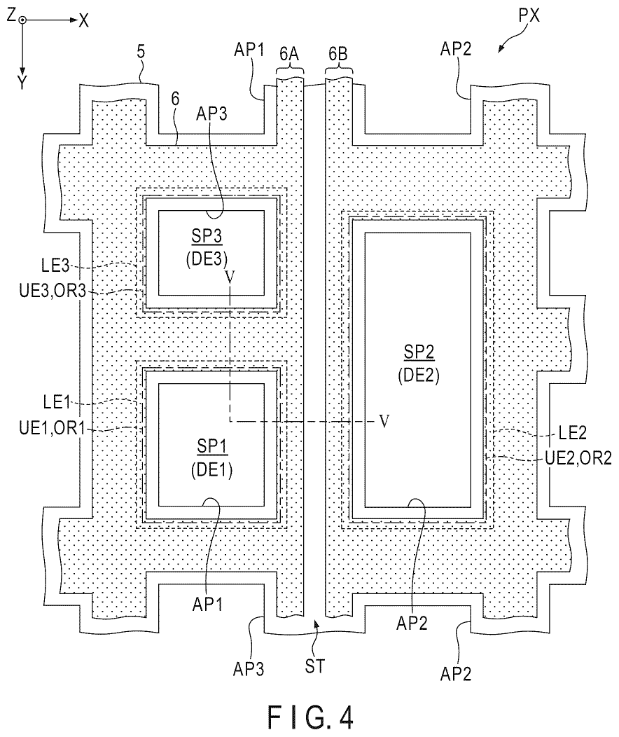

FIG. 4 is a schematic plan view showing an example of the layout of the subpixels SP1, SP2, and SP3 which constitute one pixel PX. In the example of FIG. 4, the subpixels SP1 and SP3 are arranged in the Y-direction. Further, the subpixels SP1 and SP3 are aligned with the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 4.

A rib layer 5 is provided in the display area DA. The rib layer 5 has pixel apertures AP1, AP2, and AP3 in the respective subpixels SP1, SP2, and SP3. In the example of FIG. 4, each of the pixel apertures AP1, AP2, and AP3 has a rectangular shape. The planar size of the pixel aperture AP1 is greater than the pixel aperture AP3. The planar size of the pixel aperture AP2 is greater than the pixel aperture AP1. The shape of the pixel apertures AP1, AP2, and AP3 is not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2. The lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines applying common voltage to the upper electrodes UE1, UE2, and UE3. The partition 6 entirely overlaps the rib layer 5 and has the same planar shape as the rib layer 5. The partition 6 surrounds the subpixels SP1, SP2, and SP3.

The partition 6 has a slit ST. In the example of FIG. 4, the slit ST passes between the subpixels SP1 and SP2 and between the subpixels SP2 and SP3 and extends in the Y-direction. The plurality of slits ST having such a shape are provided in the display area DA. From another viewpoint, the partition 6 has a plurality of segments divided by the slit ST. The partition 6 may have a connecting portion that connects at least some of these segments.

In the following description, among the partition 6 that extends in the Y-direction along the slit ST, a part on the side of the subpixels SP1 and SP3 is referred to as a partition 6A, and a part on the side of the subpixel SP2 is referred to as a partition 6B.

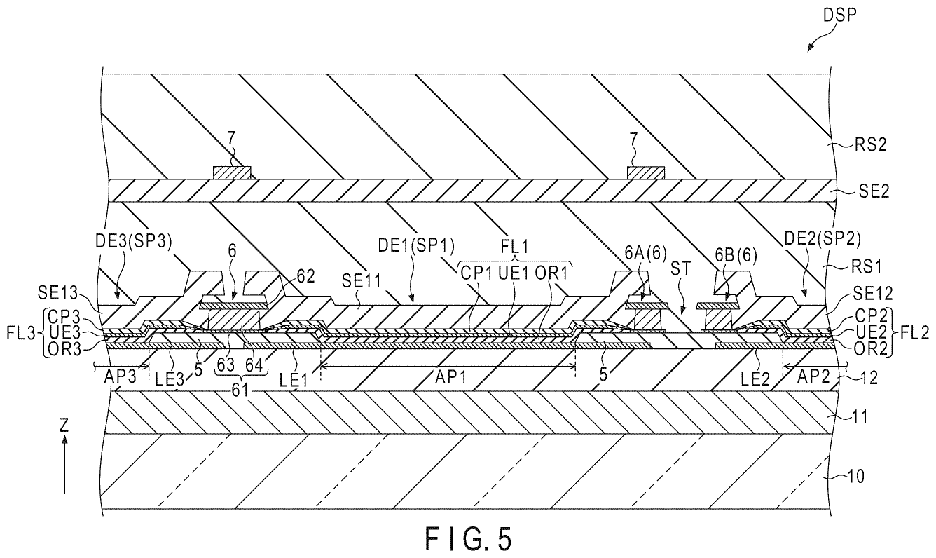

FIG. 5 is a schematic cross-sectional view of the display device DSP along the V-V line of FIG. 4. A circuit layer 11 is provided on the substrate 10 described above. The circuit layer 11 includes various circuits and lines such as the pixel circuits PC (PC1, PC2, and PC3), the signal line SL, the reset line RST, the power line PL, and the scanning lines GL1 and GL2 shown in FIG. 2 and FIG. 3. The circuit layer 11 is covered with an organic insulating layer 12. The organic insulating layer 12 functions as a planarization film planarizing irregularities formed by the circuit layer 11.

Each of the lower electrodes LE1, LE2, and LE3 is provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. The lower electrodes LE1, LE2, and LE3 are connected to the respective pixel circuits PC1, PC2, and PC3 of the circuit layer 11 through respective contact holes provided in the organic insulating layer 12.

The partition 6 includes a conductive lower portion 61 provided on the rib layer 5 and an upper portion 62 provided on the lower portion 61. In the example of FIG. 5, the lower portion 61 has a bottom layer 63 provided on the rib layer 5 and a stem layer 64 provided on the bottom layer 63. For example, the bottom layer 63 is formed to be thinner than the stem layer 64.

The upper portion 62 has the width greater than the lower portion 61. This configuration causes both end portions of the upper portion 62 to protrude relative to the side surfaces of the lower portion 61 (the side surfaces of the stem layer 64). That is, the partition 6 has an overhang shape in which the both end portions of the upper portion 62 protrude relative to the side surfaces of the lower portion 61. In the example of FIG. 5, both end portions of the bottom layer 63 protrude relative to the side surfaces of the stem layer 64.

The lower portion 61 is divided into two portions by the slit ST, and the upper portion 62 is divided into two portions by the slit ST. That is, the bottom layer 63, the stem layer 64, and the upper portion 62 of the partition 6A are spaced apart from those of the partition 6B via the slit ST. In the slit ST as well, the upper portions 62 of the partitions 6A and 6B respectively protrude relative to the side surfaces of the lower portion 61 (the side surfaces of the stem layer 64).

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3.

The upper electrodes UE1, UE2, and UE3 contact the lower portion 61 of the partition 6. Specifically, the upper electrodes UE1, UE2, and UE3 cover the bottom layer 63 protruding relative to the side surfaces of the stem layer 64. The upper electrodes UE1, UE2, and UE3 may cover at least a part of the side surface of the stem layer 64.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 are provided in the respective subpixels SP1, SP2, and SP3. The sealing layer SE11 continuously covers the stacked film FL1 and the subpixel SP1 and the partition 6 around them. The sealing layer SE12 continuously covers the stacked film FL2 and the subpixel SP2 and the partition 6 around them. The sealing layer SE13 continuously covers the stacked film FL3 and the subpixel SP3 and the partition 6 around them.

In the example of FIG. 5, one end of each of the sealing layers SE11 and SE13 are spaced apart from each other on the partition 6 between the display elements DE1 and DE3. The other end of the sealing layer SE11 is located on the partition 6A. The other end of the sealing layer SE12 is located on the partition 6B.

For example, gaps are formed between the respective sealing layers SE11, SE12, and SE13 and the upper portions 62 of the partitions 6, 6A, and 6B. The stacked films FL1, FL2, and FL3 may be provided in at least a part of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

In the present embodiment, a touch detection electrode 7 for detecting touch operations by a user is provided on the sealing layer SE2. To be described later, the touch detection electrode 7 has a lattice shape overlapping the partition 6 in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed, for example, of silver and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. In one example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is formed, for example, of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6 includes a lower layer formed of a metal material and an upper layer formed of a conductive oxide. In this case, for the metal material of the lower layer, titanium, a titanium nitride, molybdenum, tungsten, a molybdenum-tungsten alloy, or a molybdenum-niobium alloy may be used. Further, for a conductive oxide of the upper layer, an ITO or an IZO may be used. The upper portion 62 may comprise three or more layers. Alternatively, the upper portion 62 may be formed of a single layer. The upper portion 62 may further include a layer formed of an insulating material.

Common voltage is applied to the partition 6. This common voltage is applied to each of the upper electrodes UE1, UE2, and UE3 contacting the lower portions 61. Pixel voltages according to the video signals of the signal lines SL are applied to the lower electrodes LE1, LE2, and LE3 through the respective pixel circuits PC of the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in a red wavelength range.

In another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer containing quantum dots that are excited by the light emitted from the light emitting layers to generate the light of the colors corresponding to those of the subpixels SP1, SP2, and SP3.

The touch detection electrode 7 is formed, for example, of a metal material and has light-shielding properties. The touch detection electrode 7 may be a single layer structure or a multilayer structure. Various configurations may be applicable as the multilayer structure. For example, a three-layer structure of titanium, aluminum, and titanium (what is called a TAT) can be used.

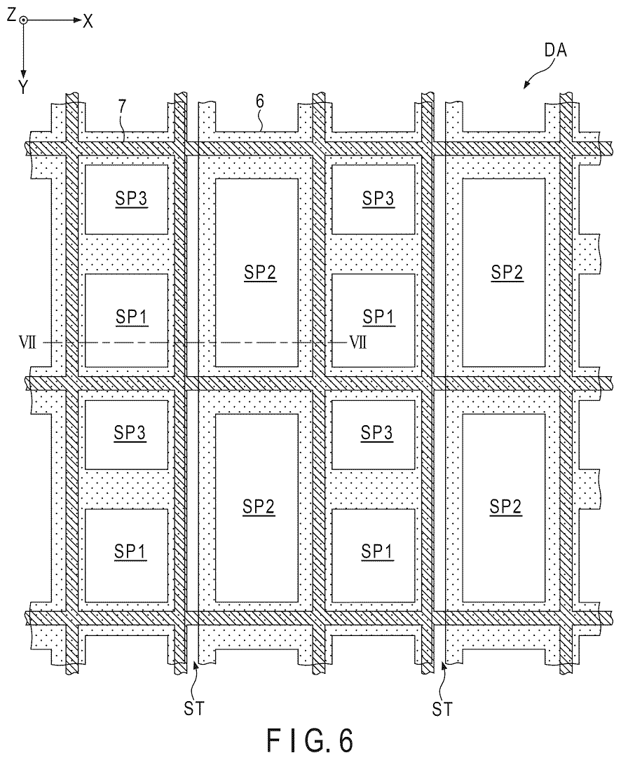

FIG. 6 is a schematic plan view showing an example of a shape applicable to the detection electrode 7. This figure shows the partition 6 with a dotted pattern and the touch detection electrode 7 with a hatched pattern.

The most part of the touch detection electrode 7 overlaps the partition 6. In the example of FIG. 6, a part extending in the Y-direction along the slit ST of the touch detection electrode 7 slightly overlaps the slit ST. Further, a part extending in the X-direction of the touch detection electrode 7 crosses the slit ST.

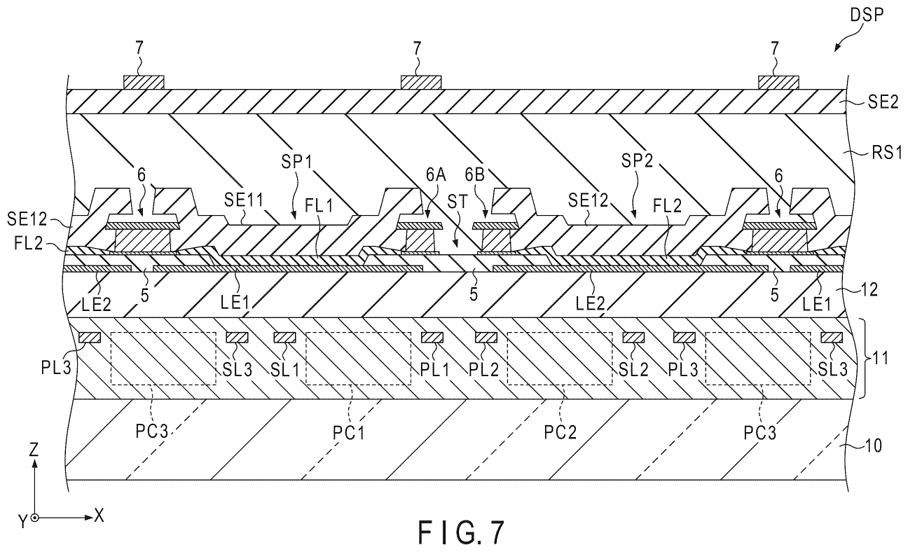

FIG. 7 is a schematic cross-sectional view of the display device DSP along the VII-VII line of FIG. 6. This figure omits the illustration of the resin layer RS2. This figure indicates approximate positions of the pixel circuits PC1, PC2, and PC3 by broken lines.

In the example of FIG. 7, the pixel circuit PC1 is located below the lower electrode LE1, and the pixel circuit PC2 is located below the lower electrode LE2. Further, the power line PL1 is located below the partition 6A, and the power line PL2 is located below the partition 6B.

The signal lines SL1, SL2, and SL3 are located below the lower electrodes LE1 and LE2. That is, the signal lines SL1, SL2, and SL3 do not overlap the slit ST in plan view. FIG. 7 shows the cross section crossing the subpixels SP1 and SP2. The configuration of the cross section crossing the subpixels SP2 and SP3 is also the same as the example of FIG. 7.

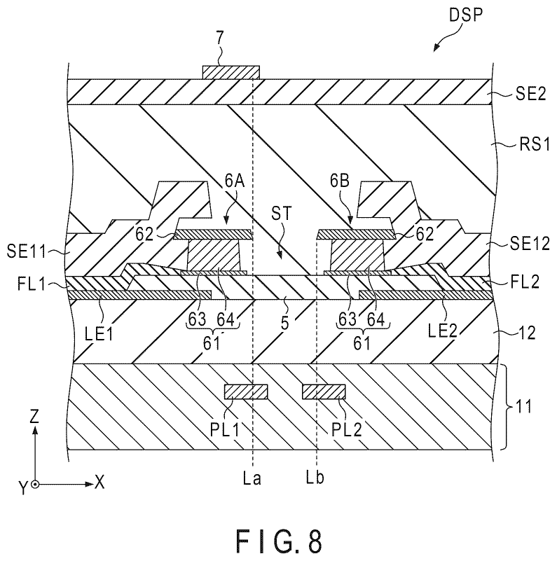

FIG. 8 is a schematic cross-sectional view showing the vicinity of the slit ST in FIG. 7 in an enlarged manner. A straight line La in the figure indicates the position of the end portion of the upper portion 62 of the partition 6A facing the slit ST. A straight line Lb indicates the position of the end portion of the upper portion 62 of the partition 6B facing the slit ST.

An end portion of the lower electrode LE1 is located below the partition 6A. An end portion of the lower electrode LE2 is located below the partition 6B. That is, in the example of FIG. 8, the lower electrodes LE1 and LE2 do not overlap the slit ST in plan view.

A part of the power line PL1 is located below the partition 6A in the Z-direction. A part of the power line PL2 is located below the partition 6B in the Z-direction. The remaining parts of the power lines PL1 and PL2 protrude into the area between the straight lines La and Lb. That is, in the example of FIG. 8, each of the power lines PL1 and PL2 partly overlaps the slit ST in plan view. In another example, the entirety of each of the power lines PL1 and PL2 may not overlap the slit ST.

A part of the touch detection electrode 7 is located above the partition 6A in the Z-direction. The remaining part of the touch detection electrode 7 protrudes into the area between the straight lines La and Lb. That is, in the example of FIG. 8, the touch detection electrode 7 partly overlaps the slit ST in plan view. In another example, the entirety of the touch detection electrode 7 may not overlap the slit ST. The touch detection electrode 7 may overlap the partition 6B instead of the partition 6A.

The slit ST contributes to increasing the transmittance of the display device DSP. In the display device DSP according to the present embodiment, the partition 6 and the lower electrodes LE1, LE2, and LE3 are provided over the entirety of the display area DA. Thus, the display device DSP has low light transmissivity from the display surface side toward the back surface side. In contrast, providing the slit ST increases the light transmissivity of the display device DSP. Thus, for example, when an optical sensor is provided on the rear surface of the display device DSP, the detection performance of the sensor can be increased.

Further, as a use form of the display device DSP, a configuration in which antennas are arranged on the rear surface and the short-range wireless communication is achieved through these antennas is assumed. In this form of use, the magnetic field during the communication may generate an eddy current in the partition 6, decreasing the signal strength. In contrast, the presence of the slit ST can suppress the generation of an eddy current having the size great enough to spread in the entire display area DA. As a result, this slit ST can suppress decreases in the signal strength.

As described below, the configuration according to the present embodiment can increase the touch detection accuracy using the touch detection electrode 7.

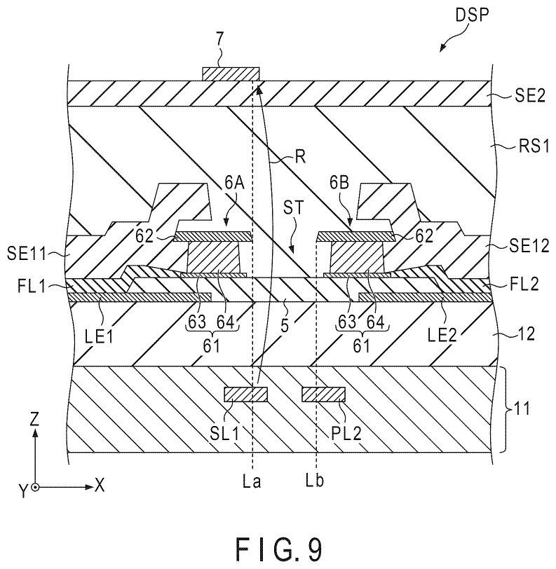

FIG. 9 is a schematic cross-sectional view showing the configuration according to a comparative example of the present embodiment. In this comparative example, the signal line SL1 is provided in the vicinity of the slit ST. A voltage of the signal line SL1 greatly varies according to a video signal. Thus, as indicated by an arrow R, a waveform of the video signal acts on the touch detection electrode 7 as noise through the slit ST and may cause an erroneous detection of touch operations.

The configuration according to the comparative example may occur when the signal line SL1 and the power line PL1, the signal line SL2 and the power line PL2, and the signal line SL3 and the power line PL3 are all arranged with the same positional relationship in the layout shown in FIG. 3. In contrast, in the present embodiment, the positional relationship between the signal line SL1 and the power line PL1 is opposite to the positional relationship between the signal line SL2 and the power line PL2 and to the positional relationship between the signal line SL3 and the power line PL3. Thus, the signal line SL1 is located to be away from the slit ST, and thus an action of noise derived from the signal line SL1 on the touch detection electrode 7 can be suppressed. For example, the power lines PL1 and PL2 are connected to a DC power supply. Thus, the power lines PL1 and PL2 do not generate noise that acts on the touch detection electrode 7.

### Second Embodiment

The following will describe the second embodiment. Unless otherwise specified, the configuration of the display device DSP can be the same as the first embodiment.

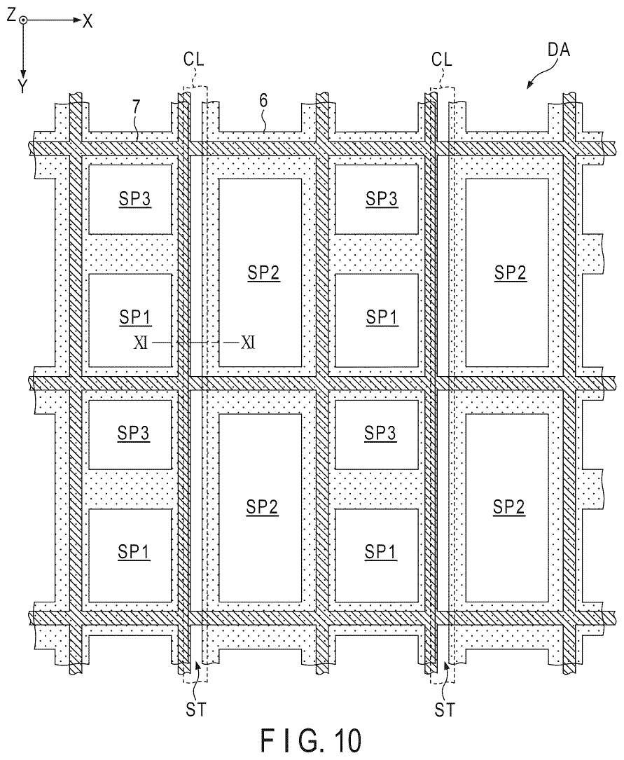

FIG. 10 is a schematic plan view of the display area DA according to the present embodiment. Shapes of the partition 6 and the touch detection electrode 7 shown in this figure are the same as those shown in FIG. 6. In the present embodiment, a transparent conductive layer CL formed of a transparent conductive material such as an ITO, an IZO or an IGZO is provided in the display area DA.

For example, the transparent conductive layer CL has a linear shape extending in the Y-direction and overlaps the slit ST in plan view. The transparent conductive layer CL does not have to be provided for all the slits ST in the display area DA. The transparent conductive layer CL may not be provided for at least one slit ST.

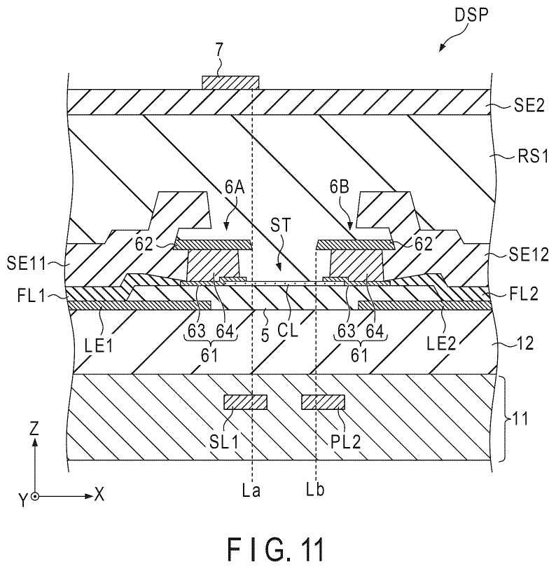

FIG. 11 is a schematic cross-sectional view of the display device DSP along the XI-XI line of FIG. 10. The transparent conductive layer CL is provided on the rib layer 5. One end portion of the transparent conductive layer CL is located between the rib layer 5 and the partition 6A. The other end portion is located between the rib layer 5 and the partition 6B. More specifically, both end portions of the transparent conductive layer CL are located between the bottom layers 63 of the respective partitions 6A and 6B and the rib layer 5.

In the example of FIG. 11, the signal line SL1 is provided in the vicinity of the slit ST as in the comparative example shown in FIG. 9. A part of the signal line SL1 is located below the partition 6A in the Z-direction. The remaining part of the signal line SL1 protrudes into the area between the straight lines La and Lb. That is, in the example of FIG. 11, the signal line SL1 partly overlaps the slit ST in plan view. In another example, the entirety of the signal line SL1 may not overlap the slit ST. Arrangement modes of the touch detection electrode 7 and the power line PL2 are the same as those shown in FIG. 8 in the first embodiment.

The configuration of the present embodiment can block an action of noise derived from the signal line SL1 on the touch detection electrode 7 by using the transparent conductive layer CL while maintaining light transmissivity at the slit ST, even when the signal line SL1 is provided in the vicinity of the slit ST. The configuration of the present embodiment can block an action of noise derived from other types of wirings such as the scanning lines GL1 and GL2 on the touch detection electrode 7 by using the conductive layer CL.

### Third Embodiment

The following will describe the third embodiment. Unless otherwise specified, the configuration of the display device DSP can be the same as those of the embodiments.

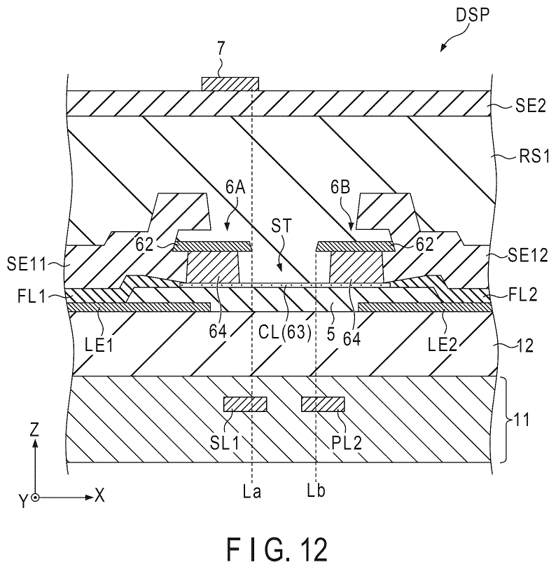

FIG. 12 is a schematic cross-sectional view of the display device DSP according to the present embodiment. As in the second embodiment, the display device DSP has the transparent conductive layer CL. However, in the present embodiment, the transparent conductive layer CL is formed of the bottom layers 63 of the partitions 6A and 6B.

From another viewpoint, in the present embodiment, the bottom layer 63 is formed of a transparent conductive material such as an ITO, an IZO or an IGZO and overlaps the slit ST in plan view.

The configuration of the present embodiment can achieve the same effects as those of the second embodiment. Using the bottom layer 63 as the transparent conductive layer CL simplifies the manufacturing process of the display device DSP compared to the second embodiment.

### Fourth Embodiment

The following will describe the fourth embodiment. Unless otherwise specified, the configuration of the display device DSP can be the same as those of the embodiments.

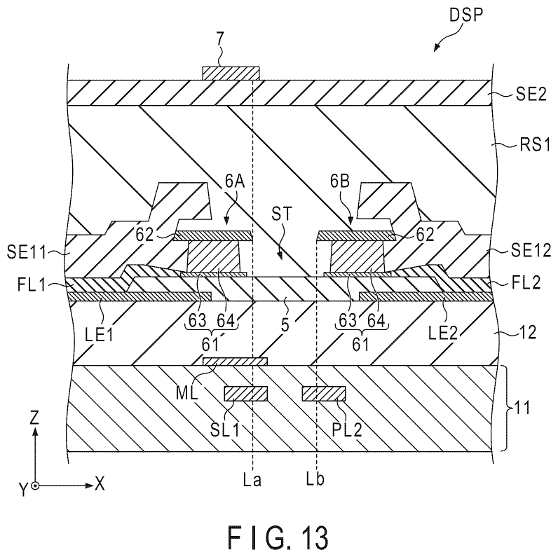

FIG. 13 is a schematic cross-sectional view of the display device DSP according to the present embodiment. In the example of FIG. 13, the signal line SL1 is provided in the vicinity of the slit ST as in the second and third embodiments. Furthermore, the metal layer ML formed of a metal material is provided above the signal line SL1.

The metal layer ML corresponds, for example, to the uppermost layer of the circuit layer 11 and is covered with the organic insulating layer 12. For example, the metal layer ML extends in the Y-direction in parallel with the signal line SL1 and overlaps the entirety of the signal line SL1 in plan view.

As in the examples of FIG. 11 and FIG. 12, a part of the signal line SL1 is located below the partition 6A in the Z-direction, and the remaining part protrudes into the area between the straight lines La and Lb. Similarly, a part of the metal layer ML is located below the partition 6A in the Z-direction, and the remaining part protrudes into the area between the straight lines La and Lb. In this manner, in the example of FIG. 13, the signal line SL1 partly overlaps the slit ST in plan view, and the metal layer ML overlaps the part overlapping the slit ST of the signal line SL1 in plan view. Arrangement modes of the touch detection electrode 7 and the power line PL2 are the same as those shown in FIG. 8 in the first embodiment.

In the example of FIG. 13, the width of the metal layer ML in the X-direction is larger than the width of the signal line SL1 in the X-direction. Further, the positions of end portions (the right-side end portions in the figure) of the signal line SL1 and the metal layer ML at the slit ST are aligned.

The metal layer ML is not floating. A predetermined voltage is applied to the metal layer ML. This predetermined voltage is not particularly limited. In one example, the power source voltage VDDEL can be used.

The configuration of the present embodiment can block an action of noise derived from the signal line SL1 on the touch detection electrode 7 by using the metal layer ML. Further, aligning the end portions of the signal line SL1 and the metal layer ML at the slit ST can minimize an influence of the metal layer ML on light transmissivity of the slit ST.

All of the display devices that can be implemented by a person of ordinary skill in the art through arbitrary design changes to the display device disclosed above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device, comprising:
a first subpixel and a second subpixel arranged in a first direction;
a partition surrounding the first subpixel and the second subpixel and having a slit extending in a second direction crossing the first direction between the first subpixel and the second subpixel;
a first pixel circuit configured to drive the first subpixel;
a second pixel circuit configured to drive the second subpixel;
a first power line applying a power source voltage to the first pixel circuit;
a second power line applying a power source voltage to the second pixel circuit;
a first signal line applying a video signal to the first pixel circuit; and
a second signal line applying a video signal to the second pixel circuit, wherein
the first signal line and the second signal line do not overlap the slit in plan view.

2. The display device of claim 1, wherein
a positional relationship between the first power line and the first signal line in the first direction is opposite to a positional relationship between the second power line and the second signal line in the first direction.

3. The display device of claim 1, further comprising:
a touch detection electrode provided above the partition.

4. The display device of claim 3, wherein
at least a part of the touch detection electrode overlaps the slit in plan view.

5. The display device of claim 1, wherein
at least a part of the first power line and at least a part of the second power line overlap the slit in plan view.

6. The display device of claim 1, wherein
the partition comprises:
a lower portion having conductivity; and
an upper portion having an end portion protruding relative to a side surface of the lower portion, wherein
the upper portion is divided into two portions spaced apart from each other by the slit, and
the lower portion is divided into two portions spaced apart from each other by the slit.

7. The display device of claim 1, wherein
the first subpixel includes:
a first lower electrode to which a voltage is applied from the first pixel circuit;
a first organic layer covering the first lower electrode and emitting light in response to voltage application; and
a first upper electrode, which covers the first organic layer and to which a voltage is applied from the partition;
the second subpixel includes:
a second lower electrode to which a voltage is applied from the second pixel circuit;
a second organic layer covering the second lower electrode and emitting light in response to voltage application; and
a second upper electrode, which covers the second organic layer and to which a voltage is applied from the partition, and
the first lower electrode and the second lower electrode do not overlap the slit in plan view.

8. A display device, comprising:
a first subpixel and a second subpixel arranged in a first direction;
a partition surrounding the first subpixel and the second subpixel and having a slit extending in a second direction crossing the first direction between the first subpixel and the second subpixel;
a first pixel circuit configured to drive the first subpixel;
a second pixel circuit configured to drive the second subpixel;
a first power line applying a power source voltage to the first pixel circuit;
a second power line applying a power source voltage to the second pixel circuit;
a first signal line applying a video signal to the first pixel circuit;
a second signal line applying a video signal to the second pixel circuit; and
a transparent conductive layer overlapping the slit in plan view.

9. The display device of claim 8, further comprising:
a rib layer located below the partition and having pixel apertures in the first subpixel and the second subpixel, wherein
a part of the transparent conductive layer is located between the partition and the rib layer.

10. The display device of claim 9, wherein
the partition comprises:
a conductive bottom layer;
a stem layer provided on the bottom layer; and
an upper portion having an end portion protruding relative to a side surface of the stem layer, and
a part of the transparent conductive layer is located between the bottom layer and the rib layer.

11. The display device of claim 8, wherein
the partition comprises:
a conductive bottom layer;
a stem layer provided on the bottom layer; and
an upper portion having an end portion protruding relative to a side surface of the stem layer, and
the transparent conductive layer is formed of the bottom layer.

12. The display device of claim 8, further comprising:
a touch detection electrode provided above the partition.

13. The display device of claim 12, wherein
at least a part of the touch detection electrode overlaps the slit in plan view.

14. The display device of claim 8, wherein
at least a part of the first signal line overlaps the slit in plan view.

15. A display device, comprising:
a first subpixel and a second subpixel arranged in a first direction;
a partition surrounding the first subpixel and the second subpixel and having a slit extending in a second direction crossing the first direction between the first subpixel and the second subpixel;
a first pixel circuit configured to drive the first subpixel;
a second pixel circuit configured to drive the second subpixel;
a first power line applying a power source voltage to the first pixel circuit;
a second power line applying a power source voltage to the second pixel circuit;
a first signal line applying a video signal to the first pixel circuit;
a second signal line applying a video signal to the second pixel circuit; and
a metal layer located above the first signal line, wherein
at least a part of the first signal line overlaps the slit in plan view, and
the metal layer overlaps the part of the first signal line overlapping the slit in plan view.

16. The display device of claim 15, wherein
a voltage is applied to the metal layer.

17. The display device of claim 15, wherein
the metal layer overlaps the entire first signal line in plan view.

18. The display device of claim 15, further comprising:
a touch detection electrode provided above the partition.

19. The display device of claim 18, wherein
at least a part of the touch detection electrode overlaps the slit in plan view.

20. The display device of claim 15, wherein
at least a part of the first signal line overlaps the slit in plan view.
